(19) United States
(12) Patent Application Publication
(10) Pub. No.: US 2025/0017010 A1
(43) Pub. Date: Jan. 9, 2025

(54) MEMORY DEVICE AND MANUFACTURING METHOD OF THE MEMORY DEVICE

(71) Applicant: SK hynix Inc., Icheon-si Gyeonggi-do (KR)

(72) Inventors: Won Geun CHOI, Icheon-si Gyeonggi-do (KR); Rho Gyu KWAK, Icheon-si Gyeonggi-do (KR); Jung Shik JANG, Icheon-si Gyeonggi-do (KR)

(73) Assignee: SK hynix Inc., Icheon-si Gyeonggi-do (KR)

(21) Appl. No.: 18/535,500

(22) Filed: Dec. 11, 2023

(30) Foreign Application Priority Data
Jul. 4, 2023 (KR) 10-2023-0086321

(51) Int. Cl. H10B 43/27

(52) U.S. Cl. CPC H10B 43/27

(57) ABSTRACT

A memory device may include: a stack structure including a plurality of conductive layers and a plurality of interlayer insulating layers, which are alternately stacked along a first direction, the stack structure including a cell region and a contact region, the contact region extending from the cell region and having a stepped structure; a plurality of contact plugs respectively in contact with the plurality of conductive layers in the contact region, the plurality of contact plugs extending in the first direction; and a plurality of lower pillars respectively in contact with the contact plugs, the plurality of lower pillars being located on the bottom of the contact plugs in the stack structure. Each of the plurality of lower pillars may include a liner layer in contact with the stack structure, and a pillar structure surrounded by the liner layer.

### CROSS-REFERENCE TO RELATED APPLICATION

The present application claims priority under 35 U.S.C. § 119(a) to Korean patent application number 10-2023-0086321 filed on Jul. 4, 2023, in the Korean Intellectual Property Office, the entire disclosure of which is incorporated by reference herein.

### BACKGROUND

### 1. Technical Field

The present disclosure generally relates to a memory device and a manufacturing method of the memory device, and more particularly, to a memory device including a memory block having a three-dimensional structure and a manufacturing method of the memory device.

### 2. Related Art

A memory device may include a nonvolatile memory device in which stored data is retained as it is even when power supply is interrupted. The nonvolatile memory device may be divided into a two-dimensional structure and a three-dimensional structure according to a structure in which memory cells are arranged. Memory cells of a nonvolatile memory device having a two-dimensional structure may be arranged in a single layer above a substrate, and memory cells of a non-volatile memory device having a three-dimensional structure may be stacked in a vertical direction above a substrate. Since a degree of integration of the nonvolatile memory device having a three-dimensional structure is higher than a degree of integration of the nonvolatile memory device having a two-dimensional structure, electronic devices using the nonvolatile memory device having a three-dimensional structure have recently been increasingly used.

### SUMMARY

In accordance with an aspect of the present disclosure, there is provided a memory device including: a stack structure including a plurality of conductive layers and a plurality of interlayer insulating layers, which are alternately stacked along a first direction, the stack structure including a cell region and a contact region, the contact region extending from the cell region and having a stepped structure; a plurality of contact plugs respectively in contact with the plurality of conductive layers in the contact region, the plurality of contact plugs extending in the first direction; and a plurality of lower pillars respectively in contact with the contact plugs, the plurality of lower pillars being located on the bottom of the contact plugs in the stack structure, wherein each of the plurality of lower pillars includes: a liner layer in contact with the stack structure; and a pillar structure surrounded by the liner layer.

In accordance with another aspect of the present disclosure, there is provided a method of manufacturing a memory device, the method including: forming a preliminary stack structure including a cell region and a contact region, the contact region extending from the cell region and having a stepped structure by alternately stacking a plurality of first material layers and a plurality of second material layers in a first direction; forming a plurality of openings penetrating the preliminary stack structure in the contact region; forming a stack structure by replacing the plurality of first material layers with a plurality of third material layers; forming a plurality of lower pillars each including a liner layer in contact with the stack structure and a pillar structure, the pillar structure surrounded by the liner layer, such that steps formed with the plurality of third material layers are exposed in the stepped structure; and forming a plurality of contact plugs respectively in contact with the steps of the plurality of third material layers on the plurality of lower pillars in the plurality of openings.

In accordance with still another aspect of the present disclosure, there is provided a method of manufacturing a memory device, the method including: forming a preliminary stack structure in which a plurality of first material layers and a plurality of second material layers are stacked in a stepped structure, forming a plurality of pairs, each pair including one of the plurality of first material layers and one of the plurality of second material layers; forming an upper insulating layer over the preliminary stack structure; forming a plurality of openings penetrating the upper insulating layer and the preliminary stack structure; forming a stack structure by replacing the plurality of first material layers with a plurality of third material layers; forming a plurality of lower pillars, each including a liner layer and a pillar structure in first regions of the plurality of openings; and forming a plurality of contact plugs in second regions above the first regions of the plurality of openings.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory device in accordance with an embodiment of the present disclosure.

FIG. 2 is a view schematically illustrating a memory device in accordance with an embodiment of the present disclosure.

FIGS. 3A and 3B are views illustrating a cell region and a contact region of a memory device in accordance with an embodiment of the present disclosure.

FIGS. 4A to 4D are views illustrating contact plugs and lower pillars in accordance with an embodiment of the present disclosure.

FIGS. 5A to 12A, 5B to 12B, and 5C to 12C are views illustrating a manufacturing method of a memory device in accordance with an embodiment of the present disclosure.

FIG. 13 is a diagram illustrating a memory card system to which the memory device of the present disclosure is applied.

FIG. 14 is a diagram illustrating a Solid State Drive (SSD) system to which the memory device of the present disclosure is applied.

### DETAILED DESCRIPTION

The specific structural or functional description disclosed herein is merely illustrative for the purpose of describing embodiments according to the concept of the present disclosure. The embodiments according to the concept of the present disclosure can be implemented in various forms, and cannot be construed as limited to the embodiments set forth herein.

Hereinafter, exemplary embodiments of the present disclosure will be described in detail with reference to the accompanying drawings in order for those skilled in the art to be able to readily implement the technical spirit of the present disclosure.

Embodiments provide a memory device and a manufacturing method of the memory device, which can enhance the stability of manufacturing processes and improve the operational reliability of the memory device.

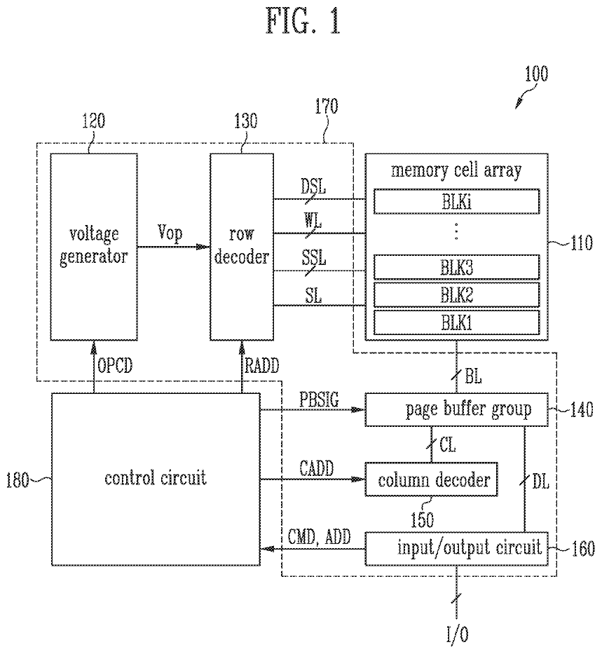

FIG. 1 is a diagram illustrating a memory device in accordance with an embodiment of the present disclosure.

Referring to FIG. 1, the memory device 100 may include a memory cell array 110, a peripheral circuit 170, and a control circuit 180.

The memory cell array 110 may include first to ith memory blocks BLK1 to BLKi. Each of the first to ith memory blocks BLK1 to BLKi may include memory cells capable of storing data. Drain select lines DSL, word lines WL, source select lines SSL, and a source line SL may be connected to each of the first to ith memory blocks BLK1 to BLKi, and bit lines BL may be commonly connected to the first to ith memory blocks BLK1 to BLKi.

The first to ith memory blocks BLK1 to BLKi may be formed in a three-dimensional structure. The memory blocks having the three-dimensional structure may include memory cells stacked in a vertical direction above a substrate.

The memory cells may store one-bit or two-or-more-bit data according to a program manner. For example, the manner in which one-bit data is stored in one memory cell may be referred to as a single level cell (SLC) manner, and the manner in which two-bit data may be stored in one memory cells is referred to as a multi-level cell (MLC) manner. The manner in which three-bit data may be stored in one memory cell is referred to as a triple level cell (TLC) manner, and the manner in which four-bit data is stored in one memory cell may be referred to as a quad level cell (QLC) manner. In addition, five-or-more-bit data may be stored in one memory cell.

The peripheral circuit 170 may be configured to perform a program operation for storing data, a read operation for outputting data stored in the memory cell array 110, and an erase operation for erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 may be configured to generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to drain select lines DSL, word lines WL, source select lines SSL, and a source line SL of a selected memory block through the row decoder 130.

The program voltages may be voltages applied to a selected word line among word lines WL in a program operation and may be used to increase a threshold voltage of memory cells connected to the selected word line. The turn-on voltages may be applied to the drain select lines DSL or the source select lines SSL and may be used to turn on drain select transistors or source select transistors. The turn-off voltages may be applied to the drain select lines DSL or the source select lines SSL and may be used to turn off the drain select transistors or the source select transistors. For example, the turn-off voltage may be set to OV. The precharge voltages may be voltages higher than OV and may be applied to the bit lines in a read operation. The verify voltages may be used in a verify operation for determining whether a threshold voltage of selected memory cells has been increased to a target level. The verify voltages may be set to various levels according to the target level and may be applied to a selected word line.

The read voltages may be applied to a selected word line in a read operation of selected memory cells. For example, the read voltages may be set to various levels according to a program manner of the selected memory cells. The pass voltages may be voltages applied to unselected word lines, among the word lines WL, in a program or read operation and may be used to turn on memory cells connected to the unselected word lines. The erase voltages may be used in an erase operation for erasing memory cells included in a selected memory block and may be applied to the source line SL.

The row decoder 130 may be configured to transmit the operating voltages Vop to drain select lines DSL, word lines WL, source select lines SSL, and a source line SL, which are connected to a selected memory block, according to a row address RADD. For example, the row decoder 130 may be connected to the voltage generator 120 through global lines and may be connected to the first to ith memory blocks BLK1 to BLKi through the drain select lines DSL, the word lines WL, the source select lines SSL, and the source line SL.

The page buffer group 140 may include page buffers (not shown) connected to each of the first to ith memory blocks BLK1 to BLKi. The page buffers (not shown) may be connected to the first to ith memory blocks BLK1 to BLKi respectively through the bit lines BL. In a read operation, the page buffers (not shown) may sense a current or a voltage of the bit lines BL, which varies according to threshold voltages of selected memory cells, and temporarily store sensed data, in response to page buffer control signals PBSIG.

The column decoder 150 may be configured to transmit data between the page buffer group 140 and the input/output circuit 160 in response to a column address CADD. For example, the column decoder 150 may be connected to the page buffer group 140 through column lines CL and may transmit enable signals through the column lines. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transmit a command CMD and an address ADD, which are received from an external controller, to the control circuit 180 through the input/output lines I/O and may transmit data received from the external controller to the page buffer group 140 through the input/output lines I/O. Alternatively, the input/output circuit 160 may output data transferred from the page buffer group 140 to the external controller through the input/output lines I/O.

The control circuit 180 may output at least one of an operation code OPCD, the row address RADD, the page buffer control signals PBSIG, and the column address CADD in response to the command CMD and the address ADD. For example, when the command CMD input to the control circuit 180 is a command corresponding to a program operation, the control circuit 180 may control the peripheral circuit 170 to perform a program operation of a memory block selected by the address ADD. When the command CMD input to the control circuit 180 is a command corresponding to a read operation, the control circuit 180 may control the peripheral circuit 170 to perform the read operation for the selected memory block selected and may output read data. When the command CMD input to the control circuit 180 is a command corresponding to an erase operation, the control circuit 180 may control the peripheral circuit 170 to perform the erase operation of the selected memory block.

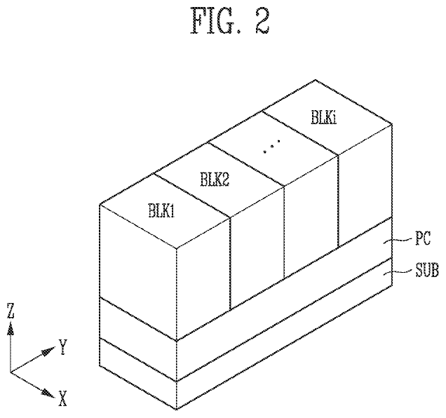

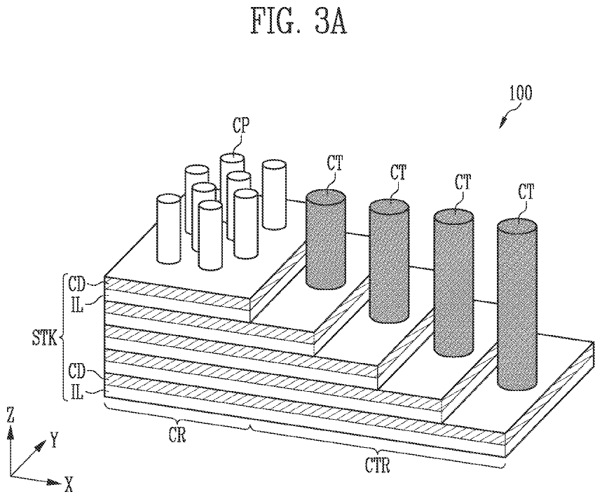

FIG. 2 is a view schematically illustrating a memory device in accordance with an embodiment of the present disclosure.

Referring to FIG. 2, the memory device may include a peripheral circuit structure PC and memory blocks BLK1 to BLKi, which are disposed on a substrate SUB. The memory blocks BLK1 to BLKi may overlap with the peripheral circuit structure PC.

The substrate SUB may be a single crystalline semiconductor layer. For example, the substrate SUB may be a bulk silicon substrate, a silicon on insulator substrate, a germanium substrate, a germanium on insulator substrate, a silicon-germanium substrate, or an epitaxial thin film formed through a selective epitaxial growth process.

The peripheral circuit structure PC may include a row decoder (130 shown in FIG. 1), a column decoder (150 shown in FIG. 1), a page buffer group (140 shown in FIG. 1), a control circuit (180 shown in FIG. 1), and the like, which constitute a circuit for controlling operations of the memory blocks BLK1 to BLKi. For example, the peripheral circuit structure PC may include an NMOS transistor, a PMOS transistor, a resistor, a capacitor, and the like, which are electrically connected to the memory blocks BLK1 to BLKi. The peripheral circuit structure PC may be disposed between the substrate SUB and the memory blocks BLK1 to BLKi.

Each of the memory blocks BLK1 to BLKi may include a source structure, bit lines, cell strings electrically connected to the source structure and the bit lines, word lines electrically connected to the cell strings, and select lines electrically connected to the cell strings. Each of the cell strings may include memory cells and select transistors, which are connected in series by a cell plug. Each of the select lines may be used as a gate electrode of a select transistor corresponding thereto, and each of the word lines may be used as a gate electrode of a memory cell corresponding thereto.

In another embodiment, the substrate SUB, the peripheral circuit structure PC, and the memory blocks BLK1 to BLKi may be stacked in a reverse order of the order shown in FIG. 2. For example, the peripheral circuit structure PC may be disposed on the memory blocks BLK1 to BLKi.

In another embodiment, unlike as shown in FIG. 2, the peripheral circuit structure PC may be disposed on a partial region of the substrate SUB, which does not overlap with the memory blocks BLK1 to BLKi. For example, the peripheral circuit structure PC and the memory blocks BLK1 to BLKi may be respectively disposed on regions of the substrate SUB, which do not overlap with each other.

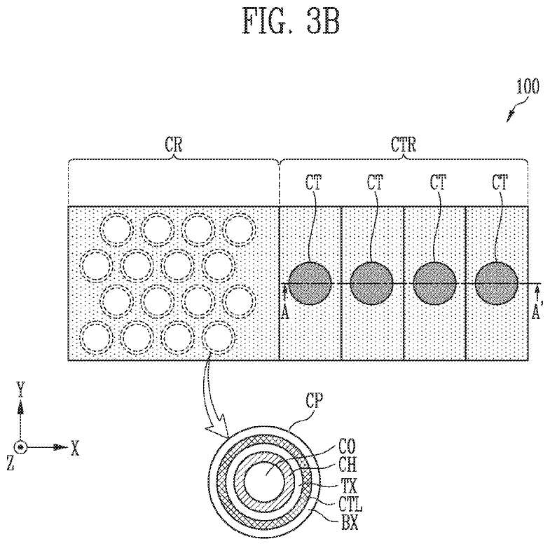

FIGS. 3A and 3B are views illustrating a cell region and a contact region of a memory device, in accordance with an embodiment of the present disclosure. FIG. 3A is a perspective view illustrating a cell region CR and a contact region CTR of the memory device 100. FIG. 3B is a plan view illustrating a layout of the cell region CR and the contact region CTR of the memory device 100.

Referring to FIGS. 3A and 3B, the memory device 100 may include a stack structure STK in which conductive layers CD and interlayer insulating layers IL are alternately stacked in a Z direction. The stack structure STK may extend in an X direction and a Y direction. The stack structure STK may include a cell region CR and a contact region CTR extending in the X direction from the cell region CR. The contact region CTR may have a stepped structure having a plurality of steps. Each of the plurality of steps may include one conductive layer CD and one interlayer insulating layer IL. Each of the steps may expose a conductive layer CD corresponding thereto. For example, a top surface of each of the steps may include a portion of a top surface of the conductive layer CD.

Cell plugs CP may extend in the Z direction in the cell region CR of the stack structure STK. The cell plugs CP may penetrate the cell region CR of the stack structure STK in the Z direction. Each of the cell plugs CP may include a memory layer having a cylindrical shape. The memory layer may include a blocking layer BX, a charge trap layer CTL formed along an inner wall of the blocking layer BX, a tunnel insulating layer TX formed along an inner wall of the charge trap layer or a combination of at least two thereof. Each of the cell plugs CP may include a channel layer CH formed along an inner wall of the tunnel insulating layer TX and a core pillar CO formed inside the channel layer CH. The blocking layer BX and the tunnel insulating layer TX may be formed of an oxide layer (e.g., a silicon oxide layer) an oxynitride layer (e.g., a silicon oxynitride layer0, or any combination thereof. The charge trap layer CTL may be a charge storage layer and may include a nitride layer or a variable resistance material. The channel layer CH may be formed of a conductive layer, e.g., a doped silicon layer. In another example, the channel layer CH may be replaced with an electrode structure. The core pillar CO may be formed of an insulating layer or a conductive layer. The blocking layer BX, the charge trap layer CTL, the tunnel insulating layer TX, the channel layer CH, and the core pillar CO, which are formed in the cell plug CP, may extend in the Z direction. A capping layer for improving electrical characteristics of select transistors included in each cell string may be further formed on the top of the core pillar CO.

Contact plugs CT may be formed in the contact region CTR of the stack structure STK. The contact plugs CT may respectively correspond to the plurality of steps included in the stepped structure in the contact region CTR. For example, each of the contact plugs CT may be connected to a conductive layer CD included in any one step, among the plurality of steps. The contact plugs CT may be respectively in contact with the conductive layers CD and may extend in the Z direction.

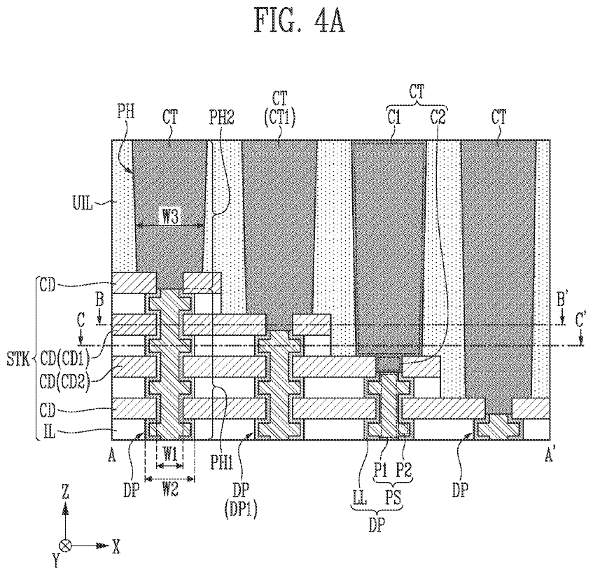

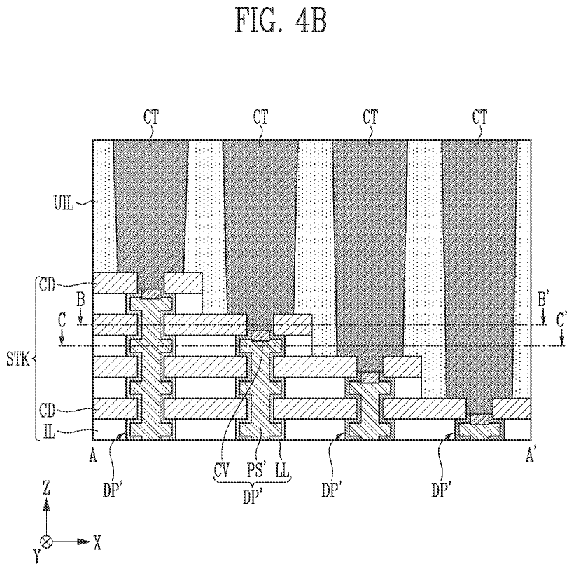

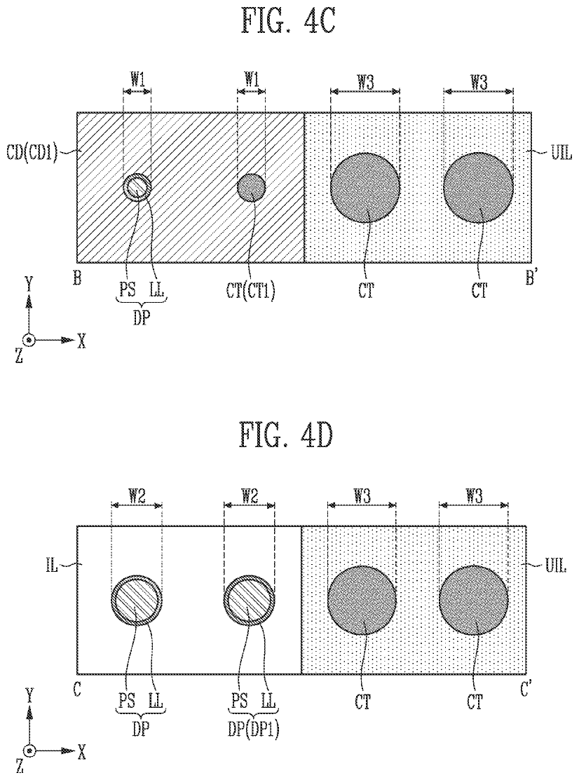

The number of cell plugs CP and contact plugs CT are not limited to numbers shown in FIGS. 3A and 3B and may vary according to an area of the stack structure STK or a stacked number of the conductive layers CD and the interlayer insulating layers IL. In addition, the positions of cell plugs CP and contact plugs CT are not limited to positions shown in FIGS. 3A and 3B, and the cell plugs CP and the contact plugs CT may be formed at various positions as long as they include features described in FIGS. 4A to 4D.

FIGS. 4A to 4D are views illustrating contact plugs and lower pillars in accordance with an embodiment of the present disclosure. FIG. 4A is a sectional view, in accordance with a first embodiment of the present disclosure, which corresponds to a section taken along line A-A′ shown in FIG. 3B. FIG. 4B is a sectional view in accordance with a second embodiment of the present disclosure, which corresponds to the section taken along the line A-A′ shown in FIG. 3B. FIG. 4C is a sectional view corresponding to a section taken along line B-B′ shown in FIGS. 4A and 4B. FIG. 4D is a sectional view corresponding to a section taken along line C-c′ shown in FIGS. 4A and 4B.

Referring to FIG. 4A, a stack structure STK may include conductive layers CD and interlayer insulating layers IL, which are alternately stacked along the Z direction. The conductive layers CD may include a first conductive layer CD1 and a second conductive layer CD2 located under the first conductive layer CD1. The stack structure STK may include a cell region CR and a contact region CTR as shown in FIGS. 3A and 3B, and a portion of the contact region CTR is illustrated in FIG. 4A. The conductive layers CD and the interlayer insulating layers IL may have a stepped structure in the contact region CTR, and steps formed with the respective conductive layers CD may be exposed by the stepped structure. For example, a portion of the first conductive layer CD1 and a portion of the second conductive layer CD2 may be exposed in each step. The second conductive layer CD2 may extend longer in the X direction than the first conductive layer CD1.

An upper insulating layer UIL covering the stack structure STK may be disposed over the stack structure STK. The upper insulating layer UIL may cover the stepped structure of the stack structure STK. The upper insulating layer UIL may have a substantially flat top surface.

Contact plugs CT may be in contact with the conductive layers CD, respectively. The contact plugs CT may be in contact with the steps of the conductive layers CD, respectively. The contact plugs CT may be electrically connected to the conductive layers CD, respectively. For example, a first contact plug CT1 might not be connected to the second conductive layer CD2. Each of the contact plugs CT may extend in the Z direction. For example, the contact plugs CT may penetrate the upper insulating layer UIL. The upper insulating layer UIL may fill a space between contact plugs CT. In an embodiment, the contact plugs CT may be arranged to be spaced apart from each other in the X direction. In another embodiment, unlike as shown in FIG. 4A, the contact plugs CT may be arranged to be spaced apart from each other in the Y direction. In still another embodiment, the memory device 100 may further include contact plugs spaced apart from each other in the Y direction with respect to the contact plugs CT shown in FIG. 4A. In addition, the number of the contact plugs CT, the direction in which the contact plugs CT are arranged, or the positions at which the contact plugs CT are arranged may be variously changed.

Lower pillars DP may overlap with the contact plugs CT, respectively. The lower pillars DP may be in contact with the contact plugs CT, respectively. Bottom surfaces of the contact plugs CT may be in contact with top surfaces of the lower pillars DP, respectively. For example, a first lower pillar DP1 may be located below the first contact plug CT1 in the stack structure STK, and the first lower pillar DP1 may penetrate at least a portion of the stack structure STK below the first contact plug CT1. The first lower pillar DP1 may overlap with the first contact plug CT1. A top surface of the first lower pillar DP1 may be in contact with a bottom surface of the first contact plug CT1. In the present disclosure, the lower pillar DP may be designated or understood as a dummy pillar.

The lower pillars DP may be located below the contact plugs CT in the stack structures STK. Each of the lower pillars DP may penetrate at least a portion of the stack structure STK while being below each of the contact plugs CT, respectively. For example, the first lower pillar DP1 may penetrate conductive layers CD and interlayer insulating layers IL, which are located below the first conductive layer CD1. The lower pillars DP may penetrate at least one conductive layer CD and at least one corresponding interlayer insulating layer IL, which are included in the stack structure STK. For example, the first lower pillar DP1 may penetrate conductive layers CD and their corresponding interlayer insulating layers IL, which are disposed below the first conductive layer CD1, among the conductive layers CD and the interlayer insulating layers IL, which are included in the stack structure STK. For example, the first lower pillar DP1 may penetrate the second conductive layer CD2. The first lower pillar DP1 might not completely penetrate the first conductive layer CD1, but other lower pillars DP may fully penetrate the first lower pillar DP1. The second conductive layer CD2 may be penetrated by the first lower pillar DP1 and may be penetrated by other lower pillars DP other than the first lower pillar DP1. In addition, an interlayer insulating layer IL corresponding to the first conductive layer CD1, disposed between the first conductive layer CD1 and the second conductive layer CD2, may be penetrated by the first lower pillar DP1 and may be penetrated by other lower pillars DP other than the first lower pillar DP1.

Each of the lower pillars DP may be formed of at least two different materials. Each of the lower pillars DP may include a liner layer LL in contact with the stack structure STK and a pillar structure PS surrounded by the liner layer LL. The liner layer LL may surround the pillar structure PS. The pillar structure PS may be spaced apart from the stack structure STK by the liner layer LL. For example, the liner layer LL may be formed of a material (e.g., an oxide layer, a nitride layer, an oxynitride layer, or an oxide layer doped with a metal) capable of insulating the conductive layers CD from each other. In addition, the pillar structure PS may be formed of poly-silicon (e.g., undoped poly-silicon) or an oxide layer.

The upper insulating layer UIL and the stack structure STK may be opened by openings PH. The openings PH may penetrate the upper insulating layer UIL and the stack structure STK in the Z direction. The openings PH may be filled with the lower pillars DP and the contact plugs CT, respectively. For example, each of the openings PH may include a first region PH1 in which a lower pillar DP is located and a second region PH2 in which a contact plug CT is located. The lower pillars DP may be located in first regions PH1 of the openings PH, and the contact plugs CT may be located in second regions PH2 of the openings PH. The first regions PH1 of the openings PH may be located in the stack structure STK. The second regions PH2 of the openings PH may penetrate the upper insulating layer UIL and may extend into a conductive layer CD exposed at each step among the conductive layers CD included in the stack structure STK. Heights of the first regions PH1 in the respective openings PH may be different from one another, and heights of the second regions PH2 in the respective openings PH may be different from one another. However, total heights of the openings PH may be substantially the same.

A width of the opening PH in the X direction or the Y direction may vary according to a position on a Z axis. Although a width in the X direction is mainly illustrated in FIG. 4A, a description of the width in the X direction may be applied to a width in the Y direction. The opening PH may penetrate the conductive layers CD with a first width W1 and may penetrate the interlayer insulating layers IL with a second width W2 that is greater than the first width W1. Also, the opening PH may penetrate the upper insulating layer UIL with a third width that is greater than the second width W2. Due to a difference in etching speed between the upper insulating layer UIL and the interlayer insulating layer IL, a width (e.g., the third width W3) with which the opening PH penetrates the upper insulating layer UIL may be greater than a width (e.g., the second width W2) with which the opening PH penetrates the interlayer insulating layers IL. In the present disclosure, the width with which the opening PH penetrates the upper insulating layer UIL may vary according to a position on the Z axis, but the third width W3 may be a maximum value, a minimum value, an average value, a median value, a value at a specific position specified on the Z axis, or a value determined through a constant reference among values belonging to the width of the opening PH penetrating the upper insulating layer UIL.

As the width of the openings PH varies along the Z direction, the width of the lower pillars DP may vary along the Z direction. For example, the lower pillars DP may have the first width W1 at levels corresponding to the conductive layers CD. Also, the lower pillars DP may have the second width W2 that is greater than the second width W2 at levels corresponding to the interlayer insulating layers IL.

The liner layers LL may extend along inner walls of the respective openings PH. The liner layer LL may be formed with a substantially constant width along an inner wall of each of the openings OP, the openings OP having different widths along the Z direction. Each of the pillar structures PS may include a vertical part P1 extending in the Z direction and horizontal protrusion parts P2 protruding toward the interlayer insulating layers IL from the vertical part P1. The horizontal protrusion parts P2 of the pillar structure PS may have a cylindrical shape surrounding the vertical part P1.

As the width of the openings PH varies along the Z direction, one portion of each of the contact plug CT may have the third width W3, and the other portion of each of the contact plugs CT may have the first width W1. Each of the contact plugs CT may include an extension part C1 extending in the Z direction and a protrusion part C2 protruding toward each of the lower pillars DP from the extension part C1. The extension part C1 may have the third width W3, and the protrusion part C2 may have the first width W1.

The extension parts C1 of the contact plugs CT may be formed inside the upper insulating layer UIL. For example, the extension parts C1 of the contact plugs CT may penetrate the upper insulating layer UIL. The extension parts C1 of the contact plugs CT may be in contact with top surfaces of the conductive layers CD exposed through the steps, respectively. For example, an extension part C1 of the first contact plug CT1 may be electrically connected to the first conductive layer CD1 while being in contact with the first conductive layer CD1. The first conductive layer CD1 may be penetrated with the first width W1 by the opening PH, but the extension part C1 of the first contact plug CT1 may have the third width W3. Therefore, the extension part C1 may be in contact with a top surface of the first conductive layer CD1.

The protrusion parts C2 of the contact plugs CT may be in contact with inner walls of the conductive layers CD exposed through the steps, respectively. For example, a protrusion part C2 of the first contact plug CT1 may be in contact with an inner wall of the first conductive layer CD1 exposed by the opening PH. The protrusion part C2 of the first contact plug CT1 may fill a portion of a region in which the first conductive layer CD1 is opened by the opening PH.

The protrusion parts C2 of the contact plugs CT may be in contact with the top surfaces of the lower pillars DP, respectively. For example, the protrusion part C2 of the first contact plug CT1 may protrude toward the first lower pillar DP1 from the extension part C1 of the first contact plug CT1 to be in contact with the top surface of the first lower pillar DP1. Referring to FIG. 4A, the protrusion parts C2 of the contact plugs CT may be in contact with top surfaces of pillar structures PS of corresponding lower pillars DP, respectively.

A boundary surface between the protrusion part C2 of the first contact plug CT1 and the first lower pillar DP1 may be located between the top surface and a bottom surface of the first conductive layer CD1. The protrusion part C2 of the first contact plug CT1 may be inserted into a space in which the first conductive layer CD1 is opened by the opening PH. The protrusion part C2 of the first contact plug CT1 may fill at least a portion of the space in which the first conductive layer CD1 is opened by the opening PH. For example, in the space in which the first conductive layer CD1 is opened by the opening PH, the rest of the space that is not filled by the first lower pillar DP1 may be filled with the first contact plug CT1. Therefore, in the space in which the first conductive layer CD1 is opened by the opening PH that is filled with the first contact plug CT1 and the first lower pillar DP1, a boundary surface between the first region PH1 and the second region PH2 may be located between the top surface and the bottom surface of the first conductive layer CD1.

Although FIG. 4A illustrates an embodiment in which the space in which the first conductive layer CD1 is opened by the opening PH is filled with a portion of the first lower pillar DP1 and a portion of the first contact plug CT1, the present disclosure is not limited thereto. For example, the protrusion part C2 of the first contact plug CT1 may penetrate the first conductive layer CD1, and a boundary surface between the first contact plug CT1 and the first lower pillar DP1 may be located at the same level as the bottom surface of the first conductive layer CD1.

Referring to FIG. 4B, each of lower pillars DP′ may include a liner layer LL in contact with the stack structure STK, a pillar structure PS' surrounded by the liner layer LL, and a cover pattern CV covering a top surface of the pillar structure PS′. When comparing FIGS. 4A and 4B with each other, the lower pillars DP′ shown in FIG. 4B may further include cover patterns CV. In the case shown in FIG. 4A, top surfaces of the pillar structures PS may be in contact with the bottom surfaces of the contact plugs CT. In the case shown in FIG. 4B, top surfaces of the pillar structures PS' might not be in contact with the bottom surfaces of the contact plugs CT. The pillar structures PS' shown in FIG. 4B may be spaced apart from the contact plugs CT through the cover patterns CV. For example, the cover pattern CV may be formed of an oxide layer (e.g., a silicon oxide layer), a nitride layer, an oxynitride layer, an oxide layer doped with a metal, or any combination thereof.

FIG. 4C may correspond to the section taken along the line B-B′ shown in FIGS. 4A and 4B, and FIG. 4D may correspond to the section taken along the line C-C′ shown in FIGS. 4A and 4B. However, in FIGS. 4A and 4B, other components are substantially identical to one another except for the existence of the cover patterns CV, and therefore, the section taken along the line B-B′ shown in FIG. 4A and the section taken along the line C-C′ shown in FIG. 4A will be mainly described in FIGS. 4C and 4D.

Referring to FIG. 4C, the first conductive layer CD1 may be in contact with the first contact plug CT1. The first contact plug CT1 may fill a portion of the space in which the first conductive layer CD1 is opened. On the section taken along the line B-B′, the first contact plug CT1 may have the first width W1. The other portion of the space in which the first conductive layer CD1 is opened may be filled with a lower pillar DP. The lower pillar DP may include a liner layer LL in contact with the first conductive layer CD1 and a pillar structure PS surrounded by the liner layer LL. On the section taken along the line B-B′, the lower pillar DP in contact with the first conductive layer CD1 may have the first width W1. The upper insulating layer UIL may be penetrated by contact plugs CT. On the section taken along the line B-B′, the contact plugs CT may have the third width W3.

Referring to FIG. 4D, lower pillars DP may fill spaces in which an interlayer insulating layer IL is opened. For example, the interlayer insulating layer IL may be penetrated by the lower pillars DP. The interlayer insulating layer IL may be penetrated by the first lower pillar DP1 and another lower pillar DP other than the first lower pillar DP1. Each of the lower pillars DP may include a liner layer LL in contact with the interlayer insulating layer IL and a pillar structure PS, the pillar structure PS surrounded by the liner layer LL. On the section taken along the line C-C′, each of the lower pillars DP may have the second width W2. The upper insulating layer UIL may be penetrated by contact plugs CT. On the section taken along the line C-C′, the contact plugs CT may have the third width W3.

Referring to FIGS. 4A to 4D, the openings PH penetrating the upper insulating layer UIL and the stack structure STK substantially have the same length in the Z direction. However, each of the contact plugs CT filled in the openings PH may be in contact with a conductive layer CD that becomes a target and might not be in contact with other conductive layers CD. For example, the first contact plug CT1 is in contact with the first conductive layer CD1 but might not be in contact with other conductive layers, e.g., the second conductive layer CD2. Since the lower portions of the openings PH are filled with the lower pillars DP, the contact plugs CT might not be in contact with other conductive layers CD except conductive layers CD (e.g., conductive layers CD that become targets) exposed at the respective steps. For example, since the first lower pillar DP1 is located below the first contact plug CT1, the first contact plug CT1 might not be in contact with other conductive layers CD except the first conductive layer CD1. Thus, the memory device may include the lower pillars DP that respectively overlap with the contact plugs CT and are formed in the stack structure STK, and accordingly, a punching phenomenon (e.g., a phenomenon in which a contact plug is connected to other conductive layers other than a conductive layer that becomes a target) does not occur in a manufacturing process of the memory device, or the number of punching phenomena occurring can be decreased.

In addition, the contact plugs CT may be in contact with top surfaces and inner walls exposed through the respective steps. For example, the first contact plug CT1 may be in contact with a portion of the top surface of the first conductive layer CD1 and a portion of the inner wall of the first conductive layer CD1. In accordance with the present disclosure, the area with which the contact plugs CT are in contact with the conductive layers CD may increase as compared with the existing contact plugs and the existing conductive layers, and thus, the resistance between the contact plugs CT and the conductive layers CD can be reduced.

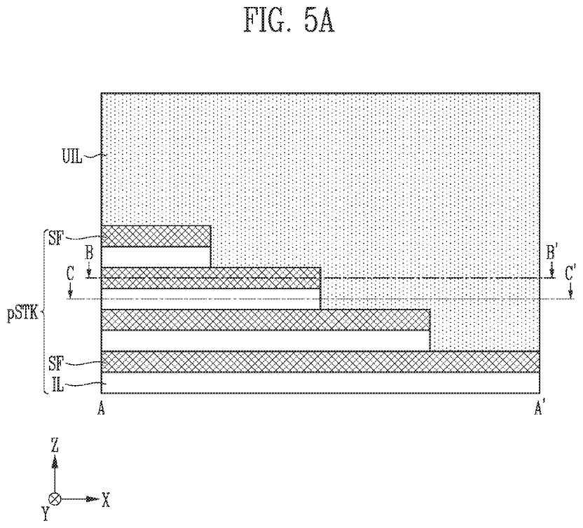

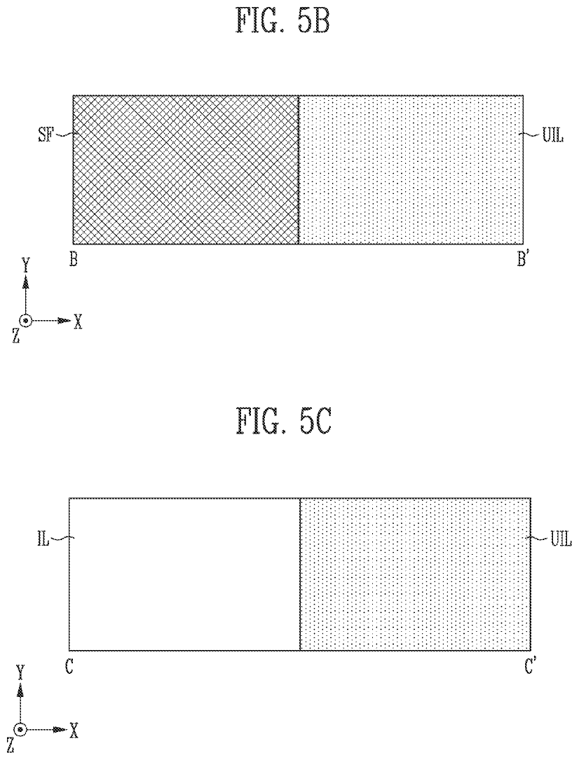

FIGS. 5A to 12A, 5B to 12B, and 5C to 12C are views illustrating a manufacturing method of a memory device in accordance with an embodiment of the present disclosure. Each of FIGS. 5A, 6A, 7A, 8A, 9A, 10A, 11A, and 12A is a sectional view corresponding to the section taken along the line A-A′ shown in FIG. 3B. Each of FIGS. 5B, 6B, 7B, 8B, 9B, 10B, 11B, and 12B is a sectional view corresponding to a section taken along line B-B′ shown in each of FIGS. 5A, 6A, 7A, 8A, 9A, 10A, 11A, and 12A. Each of FIGS. 5C, 6C, 7C, 8C, 9C, 10C, 11C, and 12C is a sectional view corresponding to a section taken along line C-C′ shown in each of FIGS. 5A, 6A, 7A, 8A, 9A, 10A, 11A, and 12A.

Referring to FIGS. 5A to 5C, first material layers SF and second material layers IL may be alternately stacked. The first material layer SF may be formed of a material that can be selectively removed in a subsequent process. The second material layer IL may be formed of an insulating material. The first material layer SF may be formed of a material having an etch selectivity that is different from an etch selectivity of the second material layer IL. For example, the first material layer SF may be formed of a nitride layer. The second material layer IL may be formed of an oxide layer (e.g., a silicon oxide layer).

Portions of the first material layers SF and the second material layers IL, which are alternately stacked, may be etched, thereby forming a preliminary stack structure pSTK having a stepped structure. The preliminary stack structure PSTK may be formed in which the first material layers SF and the second material layers IL, which form pairs, are stacked in the stepped structure. For example, portions of the first material layers SF and the second material layers IL may be etched such that each of the first material layers SF is exposed. A region, shown in FIG. 5A, may correspond to a contact region as a portion of the preliminary stack structure pSTK.

An upper insulating layer UIL may be formed over the preliminary stack structure pSTK. The upper insulating layer UIL may cover the stepped structure of the preliminary stack structure pSTK. The upper insulating layer UIL may be an oxide layer.

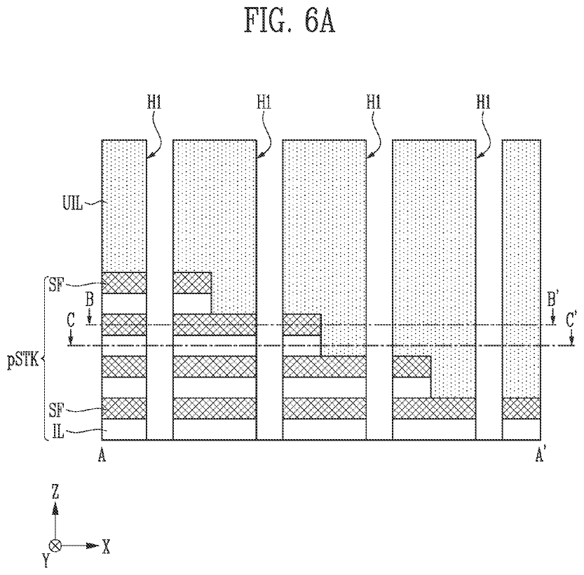

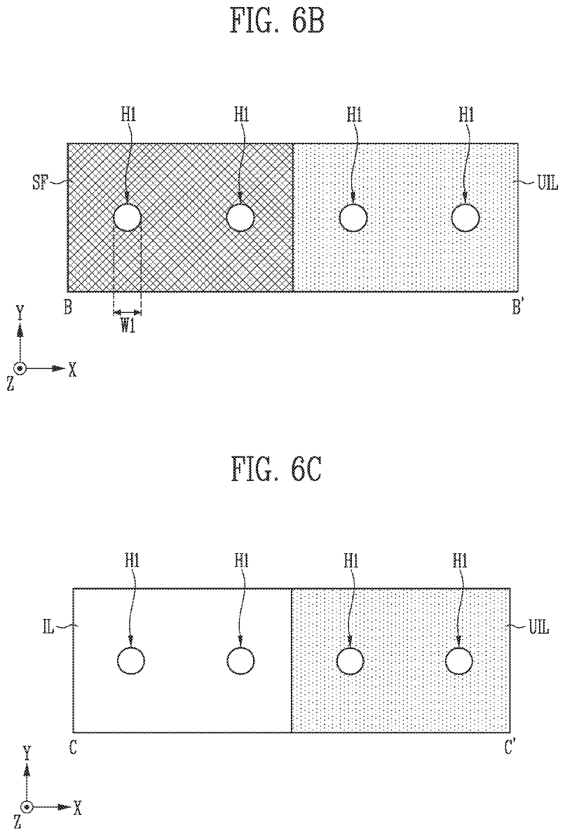

Referring to FIGS. 6A to 6C, holes H1 may be formed inside the upper insulating layer UIL and the preliminary stack structure pSTK. For example, the holes H1 may be formed, which penetrate the upper insulating layer UIL, the first material layers SF, and the second material layers IL. An anisotropic dry etching process may be performed to form the holes H1 at specified positions. Each of the holes H1 may have a first width W1.

Each of the holes H1 may penetrate the upper insulating layer UIL and the preliminary stack structure pSTK. For example, the holes H1 may be formed to penetrate the entire structure including the upper insulating layer UIL and the preliminary stack structure pSTK. Therefore, the holes H1 may be formed together with other openings included in the memory device 100. For example, referring to FIGS. 6A to 6C together with FIGS. 3A and 3B, openings for forming cell plugs CP and the holes H1 for forming contact plugs CT and lower pillars DP may be simultaneously formed. When the openings for forming cell plugs CP and the holes H1 for forming the lower pillars DP are simultaneously formed, cost and required time can be reduced as compared with when the openings and the holes H1 are separately formed through separate processes. Various openings (e.g., holes having a large aspect ratio) and the holes H1, shown in FIG. 6A, may be simultaneously formed in addition to the openings for forming the cell plugs CP.

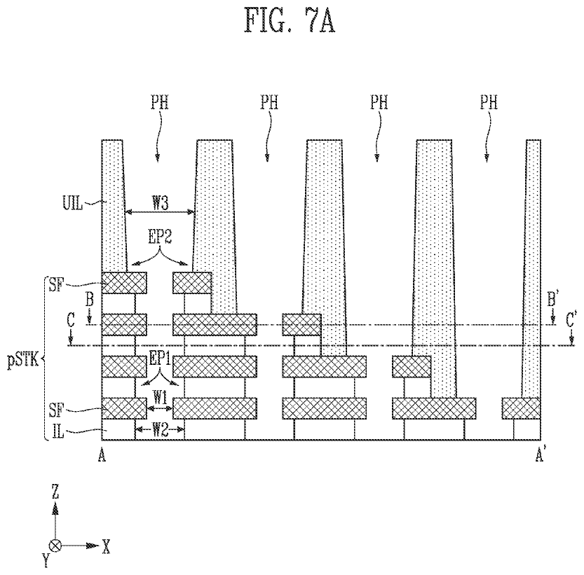

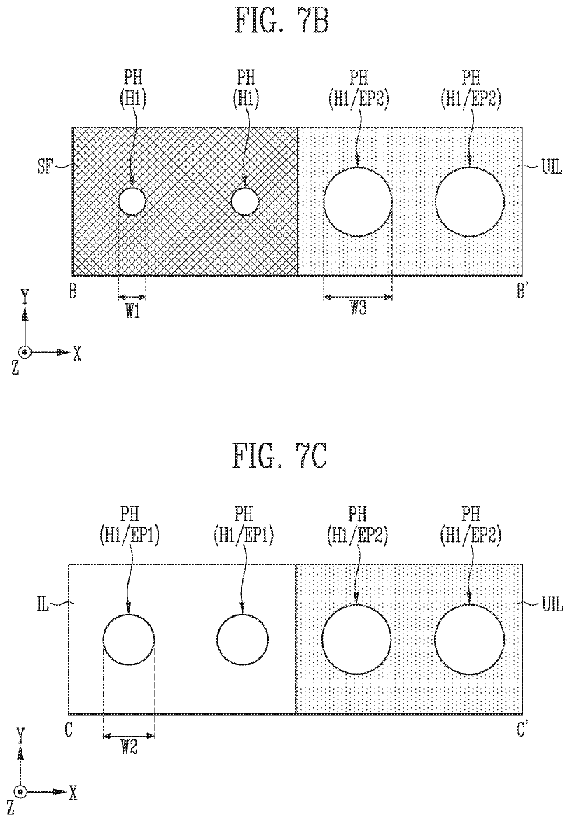

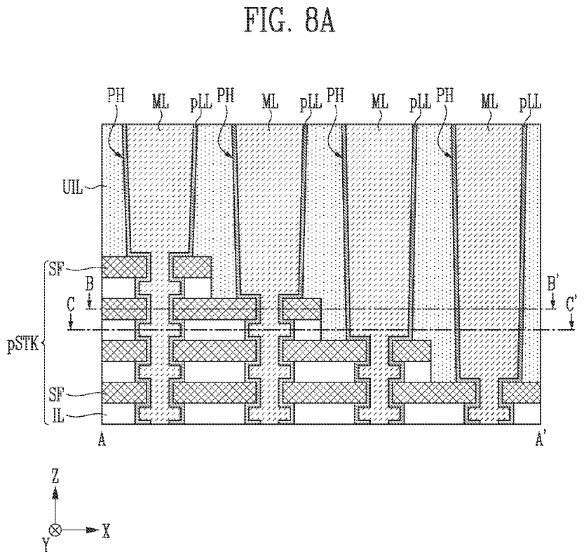

Referring to FIGS. 7A to 7C, openings PH may be formed, which penetrate the upper insulating layer UIL and the preliminary stack structure pSTK. For example, portions of the second material layers IL exposed through the holes H1 may be etched, thereby forming first extension portions EP1. In addition, portions of the upper insulating layer UIL exposed through the holes H1 may be etched, thereby forming second extension portions EP2. A process of forming the first extension portions EP1 and the second extension portions EP2 through the holes H1 may be a wet etching process for allowing the first material layers SF to remain and selectively etching portions of the second material layers IL and portions of the upper insulating layer UIL. Each of the openings PH may include a hole H1, and a first extension portion EP1 and a second extension portion EP2, which extend from the hole H1.

The openings PH may have a different width along the Z direction. Referring to FIG. 7B, openings PH may penetrate the first material layers SF with the first width W1. Since the upper insulating layer UIL and the second material layers IL are selectively etched after the holes H1 are formed, the openings PH on the section taken along the line B-B′ may have the same width (e.g., the first width W1) as the holes H1. Referring to FIG. 7C, openings PH may penetrate the second material layers IL with a second width W2. Since portions of the second material layers IL are etched, thereby forming the first extension portions EP1 after the holes H1 is formed, the openings PH on the section taken along the line C-C′ may have the second width W2 that is greater than the first width W1. Referring to FIGS. 7B and 7C, the openings PH may penetrate the upper insulating layer UIL with a third width W3. Since portions of the upper insulating layer UIL are etched, thereby forming the second extension portions EP2 after the holes H1 are formed, the openings PH on the section taken along the line B-B′ and the section taken along the line C-C′ may have the third width W3 that is greater than the first width W1.

Referring to FIGS. 7A and 7C, a width of the second extension portion EP2 may be greater than a width of the first extension portion EP1. Although the upper insulating layer UIL and the second material layers IL are simultaneously etched through the holes H1, the widths of the first extension portion EP1 and the second extension portion EP2 may be different from each other due to a difference in etching speed between the upper insulating layer UIL and the second material layers IL. For example, with respect to an etchant used in a wet etching process through the holes H1, a speed at which the upper insulating layer UIL is etched may be faster than a speed at which the second material layer IL is etched.

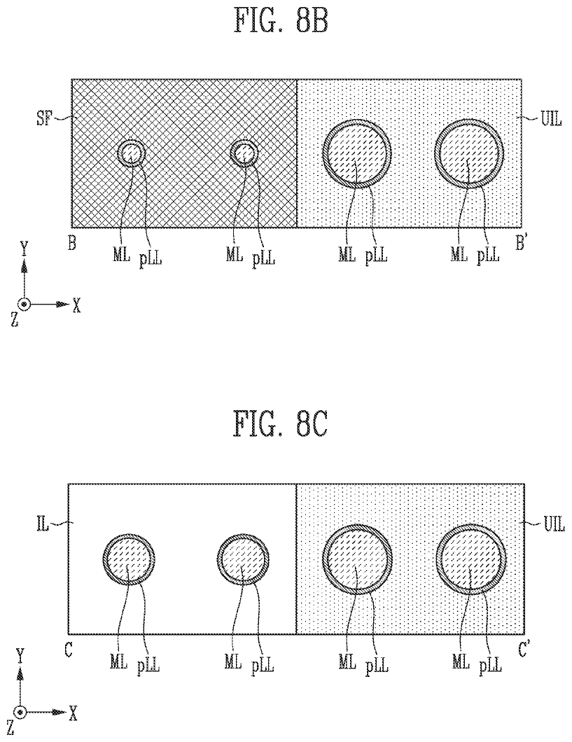

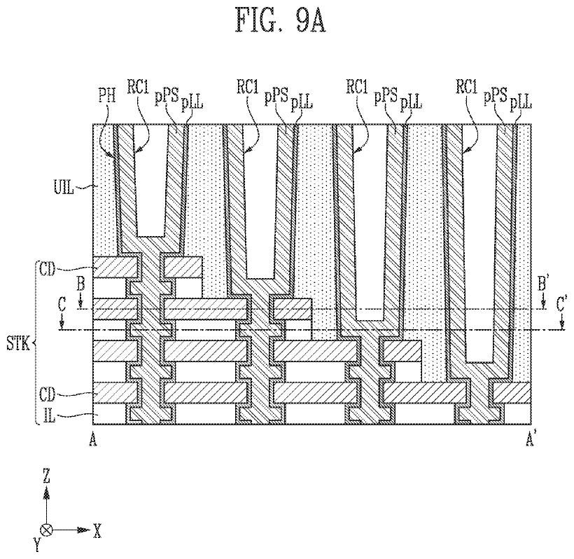

Referring to FIGS. 8A to 8C, preliminary liner layers pLL may be formed along inner walls of the openings PH. The preliminary liner layers pLL may be formed along surfaces inside the openings PH. For example, the preliminary liner layers pLL may be formed on the inner walls of the openings PH with a substantially constant thickness.

Sacrificial layers ML may be formed inside the openings PH having the preliminary liners pLL formed on the inner walls thereof. The sacrificial layers ML may be formed to be surrounded by the preliminary liner layers pLL. The sacrificial layers ML may fill the openings PH. For example, the sacrificial layers ML may be formed of a metal layer, such as tungsten.

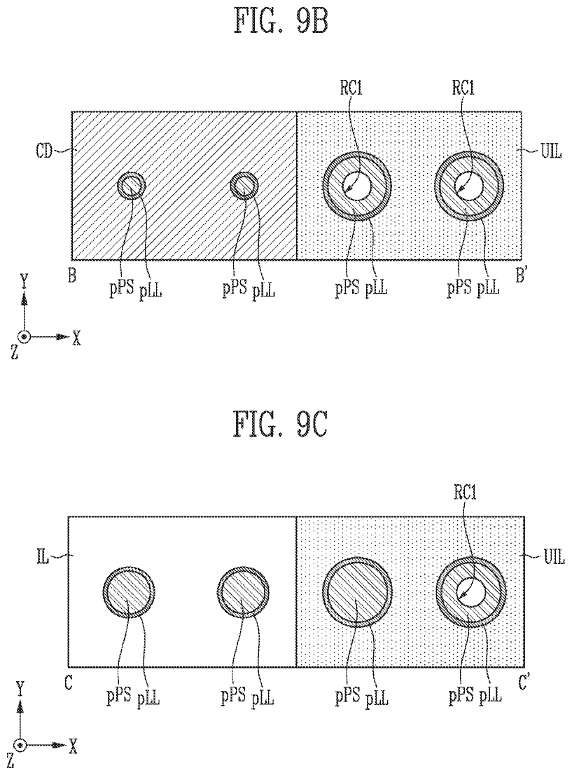

Referring to FIG. 9A to 9C, the first material layers SF may be replaced with third material layers CD, thereby forming a stack structure STK. The first material layers SF may be replaced with third material layers CD in a state in which the openings PH are filled with the preliminary liner layers PLL and the sacrificial layers ML. For example, although not shown in FIG. 9A, trenches may be formed, which penetrate the preliminary stack structure pSTK and extend in the X direction. The first material layers SF exposed through the trenches may be removed. While the first material layers SF are removed, the openings PH may be filled with the preliminary liner layers pLL and the sacrificial layers ML, which may support the second material layers IL. Regions in which the first material layers SF are removed may be filled with the third material layers CD, i.e., between the second material layers IL. The third material layers CD may be formed of at least one of tungsten (W), cobalt (Co), nickel (Ni), molybdenum (Mo), silicon (Si), and poly-silicon (poly-Si). The third material layers CD may be used as gate lines, e.g., a drain select line DSL, word lines WL, and a source select line SSL.

After the stack structure STK is formed, in which the second material layers IL and the third material layers CD are alternately stacked, the sacrificial layers ML respectively filled in the openings PH may be removed. For example, the sacrificial layers ML may be removed through a wet etching process for allowing the preliminary liner layers pLL to remain and selectively etching the sacrificial layers ML. As the sacrificial layers ML are removed, the preliminary liner layers pLL extending along the inner walls of the openings PH may be exposed.

Preliminary pillar layers pPS may be formed inside the openings PH having the preliminary liner layers pLL formed on the inner walls thereof. The preliminary pillar layers pPS may be formed on the preliminary liner layers pLL extending along the inner walls of the respective openings PH. A portion of an opening PH may be filled with each of the preliminary pillar layers pPS but might not be filled in the other portion of the opening PH. For example, the preliminary pillar layers pPS may include first recesses RC1. The preliminary pillar layers pPS may fill lower portions of the opening pH having a relatively small width (e.g., the first width W1 and the second width W2). For example, the openings PH penetrating the stack structure STK may be filled with the preliminary pillar layers pPS. The upper portions of the openings PH having a relatively large width (e.g., the third width W3) might not be completely filled with preliminary pillar layers pPS. For example, the first recesses RC1 surrounded by the preliminary pillar layers pPS may be formed inside the openings PH penetrating the upper insulating layer UIL.

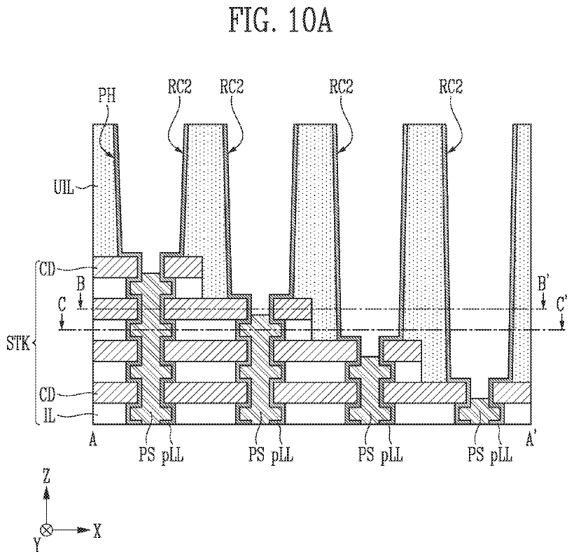

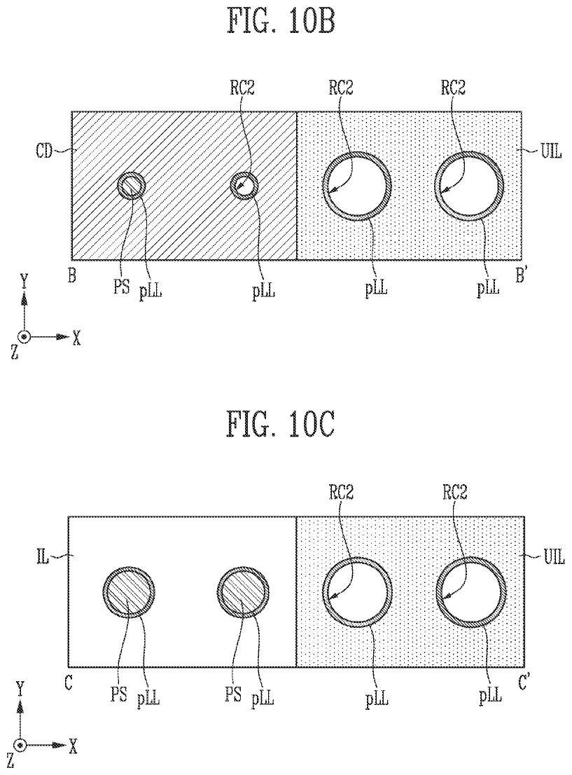

Referring to FIGS. 10A to 10C, at least portions of the preliminary pillar layers pPS formed on the inner walls of the openings PH may be removed. Portions of the preliminary pillar layers pPS may be removed through the first recesses R1 included in the preliminary pillar layers pPS. For example, portions of the preliminary pillar layers pPS may be removed through a wet etching process for allowing the preliminary liner layers pLL to remain and selectively etching the preliminary pillar layers pPS. Portions of the preliminary pillar layers pPS, which are not removed but remain, may become pillar structures PS.

As the portions of the preliminary pillar layers pPS are removed, portions of the preliminary liner layers pLL may be exposed. As the portions of the preliminary pillar layers pPS are removed, the first recesses R1 may be extended as second recesses R2. Portions of the preliminary liner layers pLL and top surfaces of the pillar structures PS may be exposed through the second recesses RC2.

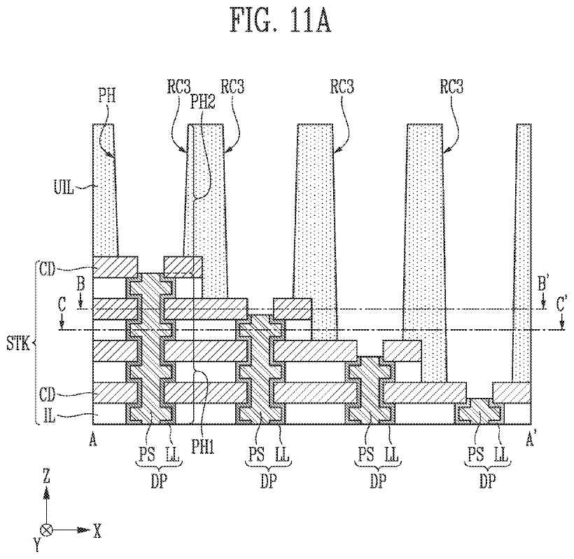

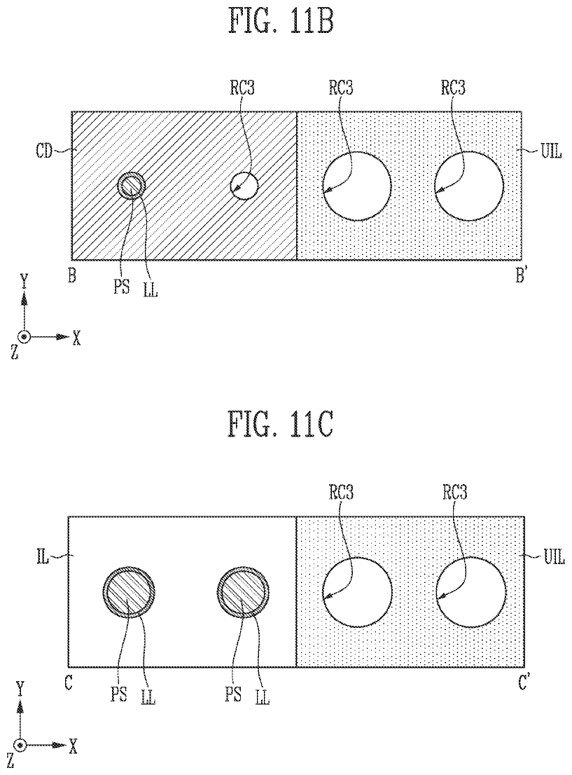

Referring to FIGS. 11A to 11C, portions of the preliminary liner layers pLL formed along the inner walls of the openings PH may be removed. Portions of the preliminary liner layers pLL exposed through the second recesses RC2 may be removed. For example, portions of the preliminary liner layers pLL may be removed through a wet etching process for allowing the upper insulating layer UIL, the third material layers CD, and the pillar structures PS to remain and selectively etching the preliminary liner layers pLL.

Portions of the preliminary liner layers pLL, which are not removed but remain, may become liner layers LL. Lower pillars DP may include the line layers LL and the pillar structures PS, respectively. The lower pillars DP may fill portions of the respective openings PH. The lower pillars DP may be formed to have a height at which steps formed with the third material layers CD can be exposed. For example, the lower pillars DP may fill first regions PH1 of the openings PH. The first regions PH1 of the openings PH may be formed in the stack structure STK.

As the portions of the preliminary liner layers pLL are removed, the upper insulating layer UIL may be exposed. As the portions of the preliminary liner layers pLL are removed, the second recesses RC2 may be extended as third recesses RC3. The upper insulating layer UIL, the third material layers CD, and the lower pillars DP may be exposed through the third recesses RC3. For example, second regions PH2 of the openings PH may correspond to the third recesses RC3. The second regions PH2 of the openings PH may penetrate the upper insulating layer UIL and may expose portions of the lower pillars DP and the third material layers CD.

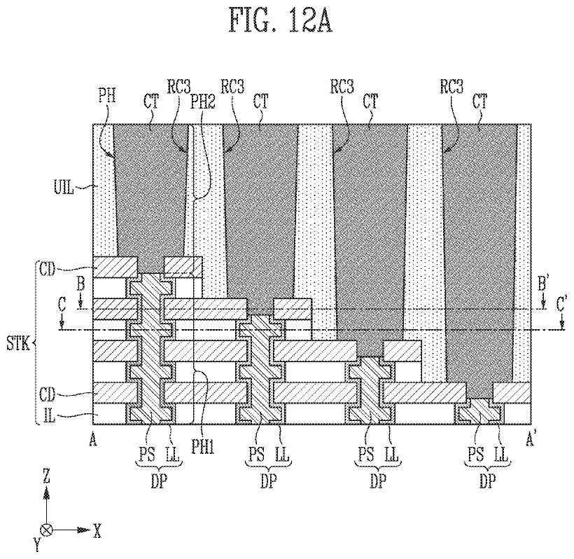

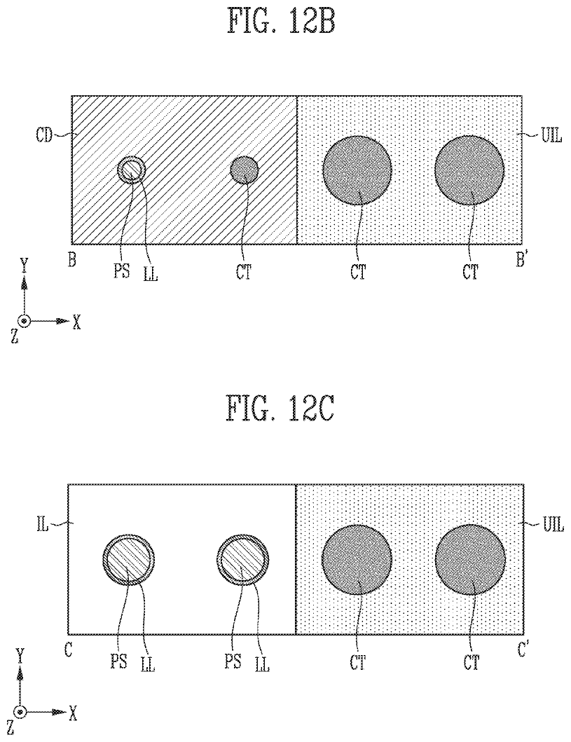

Referring to FIGS. 12A to 12C, contact plugs CT, respectively in contact with the steps of the third material layers CD, may be formed in the openings PH. The contact plugs CT may be filled in the openings PH to be formed on and to be in contact with the lower pillars DP, respectively. The contact plugs CT may fill the third recesses RC3. For example, the lower pillars DP may be formed in the first regions PH1 of the openings PH, and the contact plugs CT may be formed in the second regions PH2 of the openings PH. The contact plugs CT may be formed of a material (e.g., a metal layer) that can be electrically connected to the third material layers CD.

Referring to FIGS. 10A to 12A, the contact plugs CT may be formed on the lower pillars DP including the liner layers LL and the pillar structures PS, respectively. However, in order to form the lower pillars DP′ shown in FIG. 4B, a surface treatment process on the pillar structure PS may be added between the processes of FIG. 10A and FIG. 11A. For example, oxidation treatment may be performed on the pillar structures PS that are exposed through the second recesses R2 shown in FIG. 10A. When the oxidation treatment on the pillar structures PS is performed, the cover patterns CV, shown in FIG. 4B, may be formed on top surface of the pillar structures PS as surfaces of the pillar structures PS exposed through the second recesses RC2 are oxidized. The other portions that are not changed into the cover patterns CV may become the pillar structures PS' shown in FIG. 4B. In addition, in relation to the processes described with reference to FIG. 11A, portions of the cover patterns CV may be etched when the portions of the preliminary liner layers pLL are removed. Therefore, the lower pillars DP′ may be formed, which include the liner layers LL, the pillar structures PS′, and the cover patterns CV of which portions are etched, respectively. Since the pillar structures PS' are covered by the cover patterns CV, the pillar structures PS' might not be exposed by the third recesses RC3. In addition, in relation to the processes described with reference to FIG. 12A, the contact plugs CT may be formed in the third recesses RC3 exposing the upper insulating layer UIL, the third material layers CD, the liner layers LL, and the cover patterns CV.

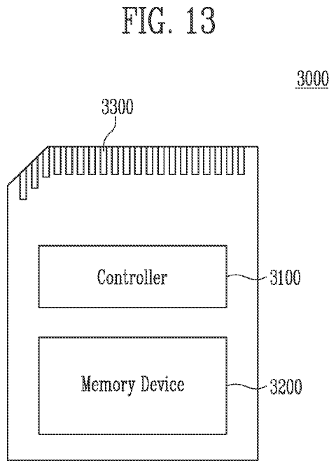

FIG. 13 is a diagram illustrating a memory card system to which the memory device of the present disclosure is applied.

Referring to FIG. 13, the memory card system 3000 may include a controller 3100, a memory device 3200, and a connector 3300.

The controller 3100 may be connected to the memory device 3200. The controller 3100 may access the memory device 3200. For example, the controller 3100 may control a program, read, or ease operation, or the controller 3100 may control a background operation of the memory device 3200. The controller 3100 may provide an interface between the memory device 3200 and a host. The controller 3100 may drive firmware for controlling the memory device 3200. For example, the controller 3100 may include components, such as a Random Access Memory (RAM), a processing unit, a host interface, a memory interface, and the error corrector.

The controller 3100 may communicate with an external device through the connector 3300. The controller 3100 may communicate with the external device (e.g., the host) according to a specific communication protocol. Exemplarily, the controller 3100 may communicate with the external device through at least one of various communication protocols, such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), firewire, a Universal Flash Storage (UFS), Wi-Fi, Bluetooth, and NVMe. For example, the connector 3300 may be defined by at least one of the above-described various communication protocols.

The memory device 3200 may include memory cells and may be configured identically to the memory device 100 shown in FIG. 1.

The controller 3100 and the memory device 3200 may be integrated into a single semiconductor device, to constitute a memory card. For example, the controller 3100 and the memory device 3200 may constitute a memory card such as a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro and eMMC), an SD card (SD, miniSD, microSD and SDHC), and a Universal Flash Storage (UFS).

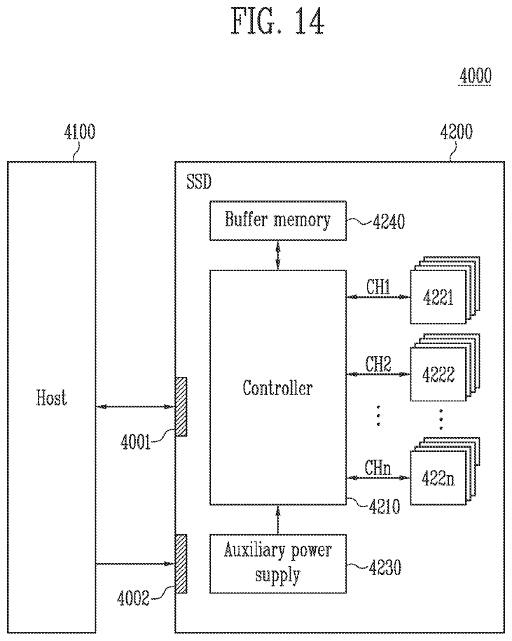

FIG. 14 is a diagram illustrating a Solid State Drive (SSD) system to which the memory device of the present disclosure is applied.

Referring to FIG. 14, the SSD system 4000 may include a host 4100 and an SSD 4200. The SSD 4200 may exchange a signal with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. Exemplarily, the signal may be a signal based on an interface between the host 4100 and the SSD 4200. For example, the signal may be a signal defined by at least one of interfaces, such as a Universal Serial Bus (USB), a Multi-Media Card (MMC), an embedded MMC (eMMC), a Peripheral Component Interconnection (PCI), a PCI express (PCIe), an Advanced Technology Attachment (ATA), a Serial-ATA (SATA), a Parallel-ATA (PATA), a Small Computer System Interface (SCSI), an Enhanced Small Disk Interface (ESDI), an Integrated Drive Electronics (IDE), a firewire, a Universal Flash Storage (UFS), a WI-FI, a Bluetooth, and an NVMe.

The plurality of memory devices 4221 to 422n may include a plurality of memory cells configured to store data. Each of the plurality of memory devices 4221 to 422n may be configured identically to the memory device 100 shown in FIG. 1. The plurality of memory devices 4221 to 422n may communicate with the controller 4210 through channels CH1 to CHn.

The auxiliary power supply 4230 may be connected to the host 4100 through the power connector 4002. The auxiliary power supply 4230 may receive power input from the host 4100 and charge the power. When the supply of power from the host 4100 is not smooth, the auxiliary power supply 4230 may provide power of the SSD 4200. Exemplarily, the auxiliary power supply 4230 may be located in the SSD 4200 or may be located at the outside of the SSD 4200. For example, the auxiliary power supply 4230 may be located on a main board and may provide auxiliary power to the SSD 4200.

The buffer memory 4240 may operate as a buffer memory of the SSD 4200. For example, the buffer memory 4240 may temporarily store data received from the host 4100 or data received from the plurality of memory devices 4221 to 422n or may temporarily store meta data (e.g., a mapping table) of the memory devices 4221 to 422n. The buffer memory 4240 may include volatile memories, such as a DRAM, an SDRAM, a DDR SDRAM, an LPDDR SDRAM, and a GRAM or nonvolatile memories, such as a FRAM, a ReRAM, an STT-MRAM, and a PRAM.

In accordance with the present disclosure, defects that may occur during a manufacturing process of contact plugs in a contact region can be reduced. Accordingly, the stability of manufacturing processes of the memory device can be enhanced, and the operational reliability of the memory device can be improved.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made based on the technological scope of the present disclosure.

Meanwhile, the exemplary embodiments of the present disclosure have been described in the drawings and specification. Although specific terminologies are used here, those are only to explain the embodiments of the present disclosure. Therefore, the present disclosure is not restricted to the above-described embodiments and many variations are possible within the spirit and scope of the present disclosure. It should be apparent to those skilled in the art that various modifications can be made based on the technological scope of the present disclosure in addition to the embodiments disclosed herein.

What is claimed is:

1. A memory device comprising:
a stack structure including a plurality of conductive layers and a plurality of interlayer insulating layers, which are alternately stacked along a first direction, the stack structure including a cell region and a contact region, the contact region extending from the cell region and having a stepped structure;
a plurality of contact plugs respectively in contact with the plurality of conductive layers in the contact region, the plurality of contact plugs extending in the first direction; and
a plurality of lower pillars respectively in contact with the contact plugs, the plurality of lower pillars being located on the bottom of the contact plugs in the stack structure,
wherein each of the plurality of lower pillars includes:
a liner layer in contact with the stack structure; and
a pillar structure surrounded by the liner layer.

2. The memory device of claim 1, wherein each of the plurality of lower pillars are respectively located in a plurality of openings penetrating the stack structure, and
wherein each of the plurality of openings penetrates the plurality of conductive layers with a first width and penetrates the plurality of interlayer insulating layers with a second width that is greater than the first width.

3. The memory device of claim 2, wherein at least a portion of each of the plurality of contact plugs has a third width that is greater than the second width.

4. The memory device of claim 2, wherein the liner layer is formed along an inner wall of each of the plurality of openings.

5. The memory device of claim 1, wherein the pillar structure includes:
a vertical part extending in the first direction; and
a horizontal protrusion part protruding toward each of the plurality of interlayer insulating layers from the vertical part.

6. The memory device of claim 1, wherein the pillar structure is spaced apart from the stack structure through the liner layer.

7. The memory device of claim 1, wherein a top surface of the pillar structure is in contact with a bottom surface of a respective contact plug, among the plurality of contact plugs.

8. The memory device of claim 1, wherein each of the plurality of lower pillars further includes a cover pattern covering a top surface of the pillar structure, and
wherein the top surface of the pillar structure is spaced apart from a respective contact plug, among the plurality of contact plugs, through the cover pattern.

9. The memory device of claim 1, wherein a first contact plug, among the plurality of contact plugs:
is electrically connected to a first conductive layer, among the plurality of conductive layers; and
is in contact with a first lower pillar, among the plurality of lower pillars.

10. The memory device of claim 9, wherein the first contact plug includes:
an extension part extending in the first direction; and
a protrusion part protruding toward the first lower pillar from the extension part.

11. The memory device of claim 10, wherein the extension part of the first contact plug is in contact with a top surface of the first conductive layer.

12. The memory device of claim 10, wherein the protrusion part of the first contact plug is in contact with an inner wall exposed by an opening and a top surface of the first lower pillar.

13. The memory device of claim 10, wherein a boundary surface between the protrusion part of the first contact plug and the first lower pillar is located between a top surface and a bottom surface of the first conductive layer.

14. The memory device of claim 10, further comprising an upper insulating layer covering the stack structure,
wherein the extension part of the first contact plug is located inside the upper insulating layer.

15. The memory device of claim 9, wherein the plurality of conductive layers further include a second conductive layer located below the first conductive layer, and
wherein the first lower pillar penetrates the second conductive layer.
